(19) United States
(12) Patent Application Publication
(10) Pub. No.: US 2019/0249823 A1
(43) Pub. Date: Aug. 15, 2019

(54) WALL-MOUNTED DAMPING FRAME FOR ELECTRONIC DEVICE

(71) Applicant: MOXA INC., New Taipei (TW)

(72) Inventor: Sung-Wei CHOU, New Taipei (TW)

(21) Appl. No.: 15/893,695

(22) Filed: Feb. 12, 2018

(51) Int. Cl. F16M 13/02; H05K 5/02; H05K 5/00; F16F 1/373

(52) U.S. Cl. CPC F16M 13/02; H05K 5/0204; H05K 5/0008; F16F 2234/02; F16F 2224/025; F16F 2230/0023; F16F 1/3735

(57) ABSTRACT

The present disclosure illustrates a wall-mounted damping frame for an electronic device. The wall-mounted damping frame uses the damping components disposed inside the fixing holes of the left damping frame and the right damping frame, the sleeves disposed in the component through holes of the damping components, and the fixing components disposed in the sleeve through holes of the sleeves, to fix the electronic device on the left damping frame and the right damping frame, so that the electronic device can be mounted on the wall through the set of damping frames. As a result, the wall-mounted effect and the damping effect for the electronic device can be achieved.

### BACKGROUND

### 1. Technical Field

The present disclosure relates to a frame, more particularly to a wall-mounted damping frame including damping frames, damping components, sleeves and fixing components, to provide damping and wall-mounted functions for an electronic device.

### 2. Description of Related Arts

The conventional manner of mounting an electronic device on a wall is to directly screw or rivet the electronic device on the wall. It is convenient to directly fix the electronic device on the wall, so as to mount the electronic device on the wall.

However, when the electronic device directly fixed on the wall is vibrated, the internal components of the electronic device may be vibrated and damaged subject to small moment of inertia; furthermore, an overly large shear stress may occur at the screwing or riveting position between the electronic device and the wall, so the screwing or the riveting part may be broken to make the electronic device fall to be damaged.

For this reason, what is needed is to develop a device to solve the conventional technology problem that the conventional wall-mounted manner for the electronic device may cause damage of the electronic device, or damage of the internal components of the electronic device.

### SUMMARY

In order to solve the problem that the conventional wall-mounted manner for the electronic device may cause damage of the electronic device or the damage of the internal components of the electronic device, the present disclosure is to provide a wall-mounted damping frame for an electronic device.

According to an embodiment, the present disclosure provides a wall-mounted damping frame for electronic device. The wall-mounted damping frame includes a set of damping frames, a plurality of damping components, a plurality of sleeves, and a plurality of fixing components. The set of damping frames includes a left damping frame and a right damping frame which have symmetrical structures. Each of the left damping frame and the right damping frame comprises at least two wall mounting members and a plurality of fixing holes. A number of damping component is equal to a number of total fixing holes, and each of the plurality of damping components is disposed in one of the plurality of fixing holes corresponding thereto and comprises a component through hole. A number of the plurality of sleeves is equal to the number of total fixing holes, and each of the plurality of sleeves is disposed in one of the component through holes of the plurality of damping components corresponding thereto, and is movable relative to the damping component corresponding thereto, and comprises a sleeve through hole. A number of the plurality of fixing components is equal to the number of total fixing holes, and the plurality of fixing components are configured to fix the electronic device with the set of damping frames through the sleeve through holes of the plurality of sleeves, respectively.

According to above-mentioned content, the difference between the conventional technology and the wall-mounted damping frame of the present disclosure is that the wall-mounted damping frame of the present disclosure uses the damping components disposed inside the fixing holes of the left damping frame and the right damping frame, and the sleeves disposed in the component through holes of the damping components, and the fixing components disposed in the sleeve through holes of the sleeves, to fix the electronic device on the left damping frame and the right damping frame, so that the electronic device can be mounted on the wall through the set of damping frames. As a result, the combination of the damping frames, the damping components, the sleeves and the fixing components can provide a damping effect to the electronic device.

By the technical means of the present disclosure, the wall-mounted effect and the damping effect for the electronic device can be achieved.

### BRIEF DESCRIPTION OF THE DRAWINGS

The structure, operating principle and effects of the present disclosure will be described in detail by way of various embodiments which are illustrated in the accompanying drawings.

FIG. 1A and FIG. 1B are exploded views of parts of a wall-mounted damping frame for an electronic device, in accordance with the present disclosure.

FIG. 2A and FIG. 2B are three-dimensional assembled views of parts of a wall-mounted damping frame for an electronic device, in accordance with the present disclosure.

FIG. 3 is a three-dimensional assembled view of a wall-mounted damping frame of the present disclosure assembled with the electronic device.

FIG. 4A and FIG. 4B are a sectional view of an assembly of damping components, sleeves, and fixing components of a wall-mounted damping frame for an electronic device, in accordance with the present disclosure.

### DETAILED DESCRIPTION OF THE PREFERRED EMBODIMENTS

The following embodiments of the present disclosure are herein described in detail with reference to the accompanying drawings. These drawings show specific examples of the embodiments of the present disclosure. It is to be understood that these embodiments are exemplary implementations and are not to be construed as limiting the scope of the present disclosure in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of components in the drawings may be exaggerated or diminished in size for the sake of clarity and convenience. Such arbitrary proportions are only illustrative and not limiting in any way. The same reference numbers are used in the drawings and description to refer to the same or like parts.

It is to be understood that, although the terms ‘first’, ‘second’, ‘third’, and so on, may be used herein to describe various components, these components should not be limited by these terms. These terms are used only for the purpose of distinguishing one component from another component. Thus, a first component discussed herein could be termed a second component without altering the description of the present disclosure. As used herein, the term “or” includes any and all combinations of one or more of the associated listed items.

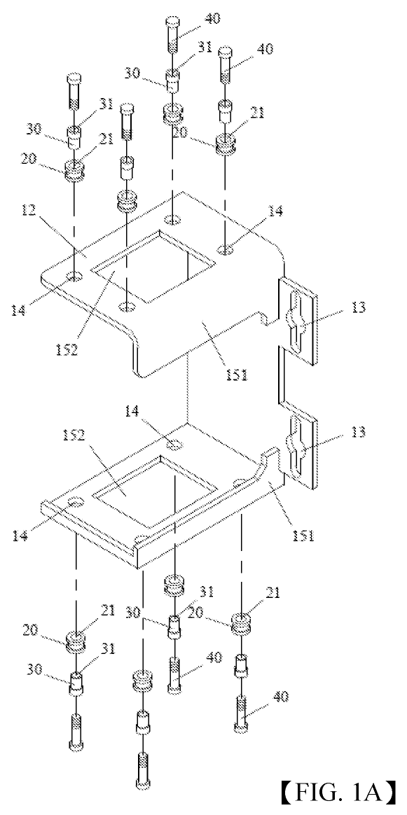

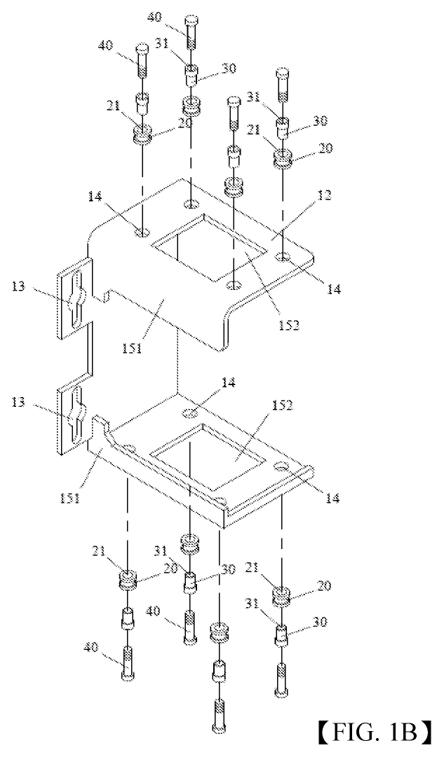

The following describes the wall-mounted damping frame for the electronic device, in accordance with the present disclosure. Please refer to FIGS. 1A and 1B. FIG. 1A and FIG. 1B are exploded views of parts of a wall-mounted damping frame for an electronic device, in accordance with the present disclosure.

According to an embodiment, the present disclosure provides a wall-mounted damping frame for an electronic device including a set of damping frames 10, a plurality of damping components 20, a plurality of sleeves 30, and a plurality of fixing components 40.

The set of damping frames 10 includes a left damping frame 11 and a right damping frame 12, the left damping frame 11 and the right damping frame 12 have symmetrical structures. Each of the left damping frame 11 and the right damping frame 12 comprises at least two wall mounting members 13 and a plurality of fixing holes 14. Besides, each of the left damping frame 11 and the right damping frame 12 includes a plurality of structural reinforcement parts 15, for example, the structural reinforcement part 15 can be a solid structural reinforcement part 151, or the the structural reinforcement part 15 can be a hollow structural reinforcement part 152.

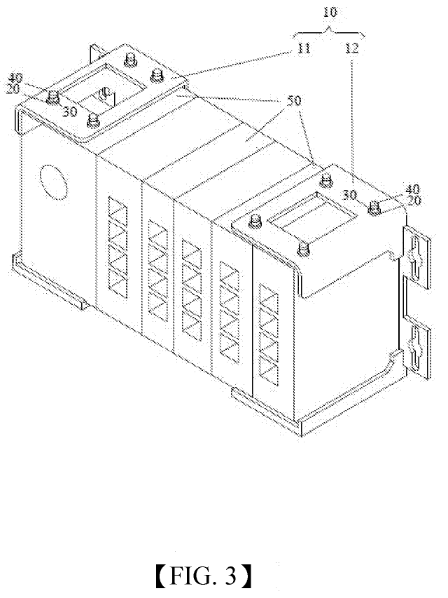

The wall mounting members 13 are configured to fix the left damping frame 11 and the right damping frame 12 on the wall by a screwing or riveting manner, that is, the set of damping frames 10 can be fixed on the wall by the wall mounting members 13 of the left damping frame 11 and the right damping frame 12, so that the electronic device 50 loaded and fixed between the left damping frame 11 and the right damping frame 12 can be mounted on the wall, as shown in FIG. 3. Preferably, each of the wall mounting members 13 can be in a geometrical shape such as a rectangular shape or a semicircular shape, but these examples are merely for exemplary illustration, and the application field of the present disclosure is not limited thereto. Each of the wall mounting members 13 can include a fixing slot which is formed with a central part in circular shape and two ends in long shape.

Preferably, the set of damping frame 10 can be made of polymer material or metal material, for example, polymer material may be epoxy resin, polymethylmethacrylate (PMMA), or polycarbonate (PC); and, the metal material may be iron, ferroalloy, or aluminum alloy; however, these examples are merely for exemplary illustration, and the application field of the present disclosure is not limited thereto.

The damping components 20 are respectively disposed in the fixing holes 14 of the left damping frame 11 and the right damping frame 12, respectively, and a number of total damping components 20 is equal to a number of total fixing holes 14 of the left damping frame 11 and the right damping frame 12. Particularly, when the number of total fixing holes 14 of the left damping frame 11 and the right damping frame 12 is 16, the number of the damping components 20 is also 16. Each of the damping components 20 comprises a component through hole 21. Preferably, the damping components 20 are made of rubber material or silica gel material.

The sleeves 30 are disposed in the component through holes 21 of the damping components 20, respectively, and a number of total sleeves 30 is equal to the number of total fixing holes 14 of the left damping frame 11 and the right damping frame 12. Particularly, when the number of total fixing holes 14 of the left damping frame 11 and the right damping frame 12 is 16, the number of the sleeves 30 is also 16.

The sleeves 30 are disposed in the component through holes 21 of the damping components 20, respectively, so that each sleeve 30 is movable relative to the corresponding damping component 20. Each sleeve 30 comprises a sleeve through hole 31. Preferably, the sleeves 30 can be made of polymer material or metal material, for example, the polymer material may be epoxy resin, PMMA, or PC; and, the metal material may be iron, ferroalloy, or aluminum alloy; however, these examples are merely for exemplary illustration, and the application field of the present disclosure is not limited thereto. It should be noted that an internal diameter of each component through hole 21 is equal to an outer diameter of each sleeve 30, and an outer diameter of one end of each sleeve 30 is larger than an outer diameter of another end of each sleeve 30.

The fixing components 40 are configured to fix the electronic device 50 through the sleeve through holes 31 of the sleeves 30, respectively. In other words, the fixing components 40 are configured to fix the electronic device 50 on the left damping frame 11 and the right damping frame 12. It should be noted that configuration of the fixing holes 14, including positions and hole diameters of the fixing holes 14, on the left damping frame 11 and the right damping frame 12 can be determined upon the fastening members of the electronic device 50. In other word, the positions and the hole diameters of the component through holes 21 of the damping components 20 disposed in the fixing holes 14, the sleeve through holes 31 of the sleeves 30 disposed in the component through holes 21, and the fixing components 40 are determined according to the fastening members of the electronic device 50.

The fixing components 40 can be made of polymer material or metal material, for example, the polymer material may be epoxy resin, PMMA, or PC; and, the metal material may be iron, ferroalloy, or aluminum alloy; however, these examples are merely for exemplary illustration, and the application field of the present disclosure is not limited thereto.

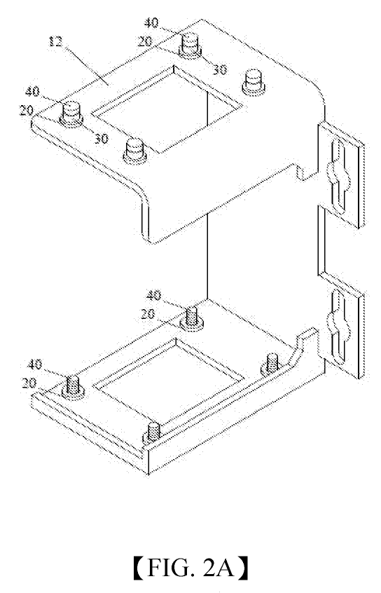

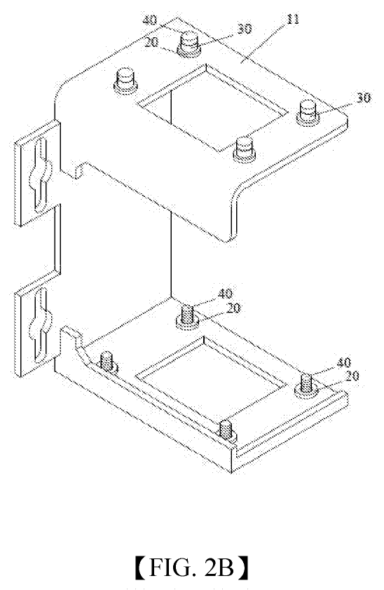

FIG. 2A and FIG. 2B show the assembly of the set of damping frames 10, the plurality of damping components 20, the plurality of sleeves 30 and the plurality of fixing components 40. FIG. 2A and FIG. 2B are three-dimensional assembled views of parts of a wall-mounted damping frame for an electronic device, in accordance with the present disclosure.

The damping components 20, the sleeves 30 and the fixing components 40 can be assembled with each other to form a rubber damping, so that the principal moments of inertia and mechanical property of the assembled frame can be improved, and the kinetic energy of the electronic device 50 in vibration environment can be converted into strain energy of the damping components 20, and the stresses applied on the set of damping frames 10, the damping components 20, the sleeves 30 and the fixing components 40 may be re-distributed, thereby preventing the set of damping frames 10, the damping components 20, the sleeves 30 or the fixing components 40 from being damaged subject to stress concentration, and effectively providing the damping effect to the electronic device 50.

Each sleeve 30 can make the stress surface of the electronic device 50 and the damping frames 10 move from inner side of the damping frames 10 to the outer side of the damping frames 10, thereby providing the space needed for energy conversion. Furthermore, the sleeves 30 can also improve the convenience in assembling the set of damping frames 10, the damping components 20, the sleeves 30 and the fixing components 40, and also prevent the damping components 20 from being broken during the operation of screwing the fixing components 40.

Please refer to FIG. 3, which shows a schematic view of the set of damping frames 10, the plurality of damping components 20, the plurality of sleeves 30 and the plurality of fixing components 40 assembled to fix the electronic device 50. FIG. 3 is a three-dimensional assembled view of a wall-mounted damping frame for an electronic device, in accordance with the present disclosure.

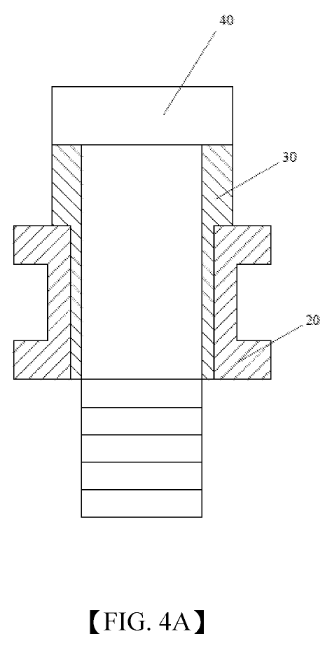

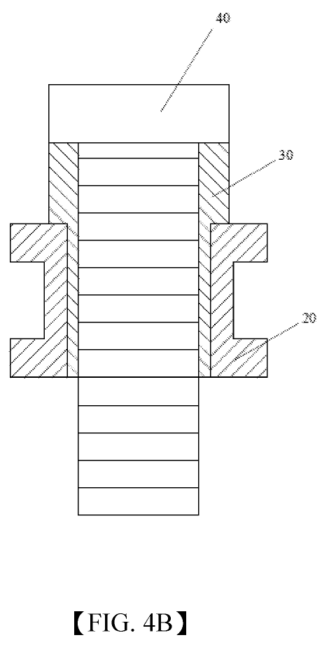

Please refer to FIG. 4A and FIG. 4B. FIG. 4A and FIG. 4B are sectional views of an assembly of the damping components, the sleeves and the fixing components of a wall-mounted damping frame for an electronic device, in accordance with the present disclosure.

As shown in FIG. 4A, a thread is formed on a part of each fixing component 40, so that the electronic device 50 can be fixed on the damping frames 10 by the screwing manner, as shown in FIG. 3. The sleeve through hole 31 of each sleeve 30 can be formed with a smooth surface inside, so that the electronic device 50 can be quickly fixed on the damping frames 10 through the fixing components 40. In another example, a thread is formed on a part of each fixing component 40, and the sleeve through hole 31 of each sleeve 30 can be formed with an inner thread thereon, so that the electronic device 50 can be fixed on the damping frames 10 by a manner of using the inner threads and the threads.

As shown in FIG. 4B, the sleeve through hole 31 of each sleeve 30 is formed with the inner thread thereon, and each fixing component 40 is not limited to have the thread on a part thereof, and the thread can be formed on entire fixing component 40, so that the electronic device 50 and the sleeves 30 can be fixed on the damping frames 10 by the screwing manner, as shown in FIG. 3. When the sleeve through hole 31 of each sleeve 30 is provided with the inner thread and each fixing component 40 is provided with the thread entirely, the electronic device 50, the sleeves 30 and the fixing components 40 can be integrated as a piece, thereby providing an overall damping effect.

In conclusion, the difference between the conventional technology and the wall-mounted damping frame of the present disclosure is that the wall-mounted damping frame of the present disclosure uses the damping components disposed inside the fixing holes of the left damping frame and the right damping frame, the sleeves disposed in the component through holes of the damping components, and the fixing components disposed in the sleeve through holes of the sleeves, to fix the electronic device on the left damping frame and the right damping frame, so that the electronic device can be mounted on the wall through the set of damping frames. As a result, the combination of the damping frames, the damping components, the sleeves and the fixing components can provide the damping effect to the electronic device.

By above-mentioned technical means, the problem that the conventional wall-mounted manner for the electronic device may cause damage of the electronic device or the damage of the internal components of the electronic device, can be solved, and the wall-mounted effect and the damping effect for the electronic device can be achieved.

The present disclosure disclosed herein has been described by means of specific embodiments. However, numerous modifications, variations and enhancements can be made thereto by those skilled in the art without departing from the spirit and scope of the disclosure set forth in the claims.

What is claimed is:

1. A wall-mounted damping frame for an electronic device, comprising:
a set of damping frames, comprising a left damping frame and a right damping frame which have symmetrical structures, wherein each of the left damping frame and the right damping frame comprises at least two wall mounting members and a plurality of fixing holes;
a plurality of damping components, wherein a number of the plurality of damping components is equal to a number of total fixing holes, and each of the plurality of damping components is disposed in one of the plurality of fixing holes corresponding thereto and comprises a component through hole;
a plurality of sleeves, wherein a number of the plurality of sleeves is equal to the number of total fixing holes, and each of the plurality of sleeves is disposed in one of the component through holes of the plurality of damping components corresponding thereto, and is movable relative to the damping component corresponding thereto, and comprises a sleeve through hole; and
a plurality of fixing components, wherein a number of the plurality of fixing components is equal to the number of total fixing holes, and the plurality of fixing components are configured to fix the electronic device with the set of damping frames through the sleeve through holes of the plurality of sleeves, respectively.

2. The wall-mounted damping frame according to claim 1, wherein each of the left damping frame and the right damping frame comprises a plurality of structural reinforcement parts.

3. The wall-mounted damping frame according to claim 2, wherein the structural reinforcement parts comprise a solid structural reinforcement part and a hollow structural reinforcement part.

4. The wall-mounted damping frame according to claim 1, wherein an internal diameter of each component through hole is equal to an outer diameter of each of the plurality of sleeves.

5. The wall-mounted damping frame according to claim 1, wherein the sleeve through hole is formed with an inner thread.

6. The wall-mounted damping frame according to claim 1, wherein an outer diameter of one end of each of the plurality of sleeves is larger than an outer diameter of another end of each of the plurality of sleeves.

7. The wall-mounted damping frame according to claim 1, wherein each of the wall mounting members is in a geometrical shape and comprises a fixing slot which is formed with a central part in circular shape and two ends in long shape.

8. The wall-mounted damping frame according to claim 1, wherein each of the damping components is made of rubber material or silica gel material.

9. The wall-mounted damping frame according to claim 1, wherein the set of damping frames, the plurality of sleeves and the plurality of fixing components are made of polymer material or metal material.
